(19) United States
(12) Patent Application Publication
(10) Pub. No.: US 2011/0312179 A1
(43) Pub. Date: Dec. 22, 2011

(54) SUBSTRATE PROCESSING METHOD AND SUBSTRATE PROCESSING APPARATUS

(75) Inventors: Takashi Nakagawa, Tokyo (JP); Eun-mi Kim, Hwasung-shi (KR); Naomu Kitano, Tokyo (JP); Kimiko Mashimo, Tokyo (JP)

(73) Assignee: CANON ANELVA CORPORATION, Kawasaki-shi (JP)

(21) Appl. No.: 13/115,410

(22) Filed: May 25, 2011

Related U.S. Application Data
(63) Continuation of application No. PCT/JP2009/071321, filed on Dec. 22, 2009.

(30) Foreign Application Priority Data
Dec. 26, 2008 (JP) 2008331693

(51) Int. Cl. H01L 21/285; B05C 11/00

(52) U.S. Cl. 438/660; 118/696; 257/E21.16

(57) ABSTRACT

The present invention provides a substrate processing method and a substrate processing apparatus, which are capable of forming a high-k dielectric film with few trapping levels due to oxygen deficiencies and hot carriers by a sputtering method in one and the same vacuum vessel. The substrate processing method according to a first embodiment of the present invention includes: a first step of heating a to-be-processed substrate (102) arranged in a film forming treatment chamber (100) and depositing a metal film on the to-be-processed substrate (102) by physical vapor deposition using a target (106); and a second step of supplying a gas containing elements for oxidizing a metal film in the film forming treatment chamber (100) to oxidize the metal film by a thermal oxidation reaction.

### CROSS-REFERENCES TO RELATED APPLICATIONS

This application is a continuation application of International Application No. PCT/JP2009/071321, filed Dec. 22, 2009, which claims the benefit of Japanese Patent Application No. 2008-331693, filed Dec. 26, 2008. The contents of the aforementioned applications are incorporated herein by reference in their entities.

### TECHNICAL FIELD

The present invention relates to a substrate processing method and a substrate processing apparatus which form an insulating film, more specially it relates to a substrate processing method and a substrate processing apparatus of a semiconductor device having a high-k dielectric film.

### BACKGROUND ART

There has been a problem of increase of a gate-leak current due to reduction in film thickness of a gate insulating film in developing a leading-edge CMOS (complementary MOS) device in which miniaturization of transistors is advancing. Moreover, in developing an MONOS (Metal Oxide Nitride Oxide Semiconductor) device in which miniaturization of non-volatile semiconductor elements is advancing, there has been a problem of maintaining a retention characteristic in spite of reduction of an operational voltage due to reduction in film thickness of a blocking layer for preventing leakage of charges accumulated in a charge accumulation layer to the side of a gate electrode.

Hence, a technology for reducing a gate-leak current and thinning the EOT (Equivalent Oxide Thickness) of a silicon oxide film by thickening a physical film layer using a high-k material as the gate insulating film of a CMOS device or the blocking layer of an MONOS device, has been investigated. As typical high-k materials, oxides containing Ta, Al, Zr, Hf, La, etc. are included.

As for means for forming films of the above-mentioned high-k materials, methods for forming a metal oxide film by a CVD (Chemical Vapor Deposition) process, an Atomic Layer Adsorption/Deposition method, and a sputtering method, are included.

In Patent Document 1, as a technology for an Atomic Layer Adsorption process of HfO₂, a technology using Hf [N(C₂H₅)₂]₄ (tetrakis (dimethylamino) hafnium) as a metal raw material gas and O₃ as an oxidizer is disclosed, where HfO₂ is formed by alternately repeating an Hf [N(C₂H₅)₂]₄ supply step, a purge step, an O₃ supply step, and a purge step in this order on a substrate.

Moreover, in Non-Patent Document 1, an Atomic Layer Adsorption process of La₂O₃ using La(i-PrCp)₃ (tris(isopropyl-cyclopentadienyl)lanthanum) as a metal raw material gas and using O₃ as an oxidizer is described.

Next, in Patent Document 2, a method for forming an oxide thin film by means of a sputtering method is disclosed, which includes a process where a first step of reactive sputtering deposition accompanied with a chemical reaction with a gas containing the element of a thin film raw material or the discharged plasma of the gas and a second step of decomposing and exciting a reactive gas at the deposition surface or near the surface using plasma that substantially does not cause sputtering to occur under an electric field capable of decomposing a gas used for oxidation in a gas atmosphere containing a gas in which deposition does not occur or occurs at a rate much smaller than that of the first step are carried out alternately for a plurality of times.

Furthermore, in Patent Document 3, a method for forming Al₂O₃ by means of a sputtering method is disclosed, where Al₂O₃ is formed by alternately repeating a step of forming an Al metal film and a step of oxidizing the Al film with plasma generated by an RF coil while introducing O₂ gas.

Furthermore, in Patent Document 4, a method for forming MOSFET by depositing a metal gate by vapor deposition on a high-k dielectric is disclosed, which includes: a annealing step of annealing a substrate on which a high-k dielectric film is deposited by vapor deposition in a thermal annealing module; and a vapor deposition step of depositing a metal gate material by vapor deposition on the annealed substrate in a metal gate vapor deposition module, wherein the annealing step and the vapor deposition step are continuously carried out without breaking a vacuum.

Furthermore, in Patent Document 5, a method for forming a hafnium silicate high-k dielectric film is disclosed, where on a silicon substrate in which a silicon oxynitride film is formed a hafnium layer is deposited by means of a sputtering method, then the substrate is continuously subjected to thermal processing in a film formation chamber, subsequently the processed substrate is taken out from inside the film formation chamber, and subjected to thermal processing in a nitrogen atmosphere so as to compensate the oxygen deficiencies in the film.

### PRIOR ART DOCUMENTS

### Patent Documents

Patent Document 1: Japanese Patent Application Laid. Open No. 2004-79753
Patent Document 2: Japanese Patent Application Laid. Open No. H6-172990
Patent Document 3: Japanese Patent Application Laid. Open No. H10-324969
Patent Document 4: Japanese Patent Application Laid. Open No. 2006-237371
Patent Document 5: International Publication No. WO 2004/008544 Pamphlet

### Non-Patent Document

Non-Patent Document 1: International electron devices meeting technical digest 2007, p539

### SUMMARY OF INVENTION

However, the above-mentioned film formation technologies have the following problems, respectively.

First, Atomic layer Adsorption/Deposition methods as disclosed in Patent Document 1 and Non-Patent Document 1 has a problem in that since a raw material gas containing C is used as a metal raw material gas, C remains in a metal film, leading to increase of electric properties such as a leak current.

Second, as indicated in Non-Patent Document 1, it is demonstrated that the thickness of La₂O₃ film for 0 to 15 cycles tends to saturate with respect to the number of cycles. Thus, Atomic layer Adsorption/Deposition method has a problem of difficulty in controlling the thickness of a metal oxide film in an ultra thin film region.

Third, the methods disclosed in Patent Document 2 and Patent Document 3 have an advantage in that the area of oxygen deficiencies in the metal oxide film deposited on a substrate is compensated by oxygen atoms. However, since oxygen plasma is used for oxidation, traps of hot carriers tend to be formed in the metal film due to plasma damage, resulting in problems of fluctuation of the threshold voltage for a CMOS device and degradation of the retention characteristic due to leakage via the traps for an MONOS device.

Fourth, since in the method disclosed in Patent Document 4, a film formation step and an annealing step are carried out in a different vessel, respectively, there occur problems of decrease in throughput and difficulty in forming a high-k insulating film with a stoichiometric composition. Particularly, in case of forming a thick insulating film, there occurs a problem of carrying out the film formation step and the annealing step many times repeatedly.

Fifth, in the method disclosed in Patent Document 5, a film formation step and an annealing step are carried out in one and the same vessel. However, in the method disclosed in Patent Document 5, a thermal treatment step is performed in a state containing a lot of oxygen deficiencies to diffuse the metal film-formed in a silicon oxide under film, thereby forming a metal silicate layer. Thus, although the method is suitable for formation of a silicate layer utilizing an interface reaction, it is not suitable for formation of the blocking film of a trap memory, because a trap layer due to the oxygen deficiencies and the interface reaction may be formed. Moreover, in Patent Document 5, it is also described that even when the oxidation step is carried out in another chamber and continuous thermal treatment is performed in a film formation chamber, it is necessary to perform thermal treatment again in a nitrogen atmosphere, because oxygen deficiencies occur in the film. Moreover, although the method disclosed in Patent Document 5 is suitable for formation of a dielectric film having a thickness of about 1 nm, there occurs a problem in that the number of steps increases when the blocking film for an MONOS device requiring to have a thickness of, for example, 5 nm or more is formed, because the film formation step and the thermal treatment step (annealing step) have to be repeated for several times. That is, in order to achieve the requirement according to the method disclosed in Patent Document 5, the steps of forming a metal film having a thickness of about 3 nm in a vessel, oxidizing the metal film in another vessel, forming a metal film having a thickness of about 3 nm on the oxidized metal film again, and oxidizing the metal film in the other vessel, . . . have to be repeated for several times. Thus, there occurs a problem in that the number of steps increases.

The present invention is devised to solve the above-mentioned problems, and the object thereof is to provide a substrate processing method and a substrate processing apparatus which are capable of forming a high-k dielectric film having few oxygen deficiencies and traps due to hot carriers in one and the same vacuum vessel by means of a sputtering method.

In order to achieve the above-mentioned object, the present invention has the following configuration.

One aspect of the present invention is a substrate processing method, comprising a first step of heating a to-be-processed substrate arranged in a vacuum vessel and depositing a metal film on the substrate by physical vapor deposition using a target; and a second step of supplying a gas containing an element for oxidizing a metal film in the vacuum vessel to oxidize the metal film by a thermal oxidation reaction.

Moreover another aspect of the present invention is a substrate processing apparatus, comprising: a film forming treatment chamber; a substrate holding table for holding a to-be-processed substrate in the film forming treatment chamber; a heating device for adjusting the temperature of the substrate holding table; an oxidation gas introduction means for introducing an oxidation gas in the film forming treatment chamber; an inert gas introduction means for introducing an inert gas in the film forming treatment chamber; a high-frequency supply means for supplying a high-frequency electric power to a target containing an element constituting a metal film; and a control mechanism, wherein when a metal film is formed on the to-be-processed substrate in the film forming treatment chamber, the control mechanism controls the heating device so as to heat the to-be-processed substrate and controls the inert gas introduction means and the high-frequency supply means so as to deposit a metal film on the to-be-processed substrate being heated, and wherein when the deposited metal film is oxidized in the film forming treatment chamber, the control mechanism controls the oxidation gas introduction means so as to supply the oxidation gas on the deposited metal film and controls the heating device so as to oxidize the metal film by a thermal oxidation reaction.

Moreover, another aspect of the present invention is a method for manufacturing a MOS-FET including a high-k dielectric film, the method comprising: a first step of heating a to-be-processed substrate arranged in a vacuum vessel and depositing a metal film on the substrate by physical vapor deposition using a target; and a second step of supplying a gas containing an element for oxidizing a metal film in the vacuum vessel to oxidize the metal film by a thermal oxidation reaction.

Moreover, another aspect of the present invention is a method for manufacturing a non-volatile memory element including a high-k dielectric film, the method comprising: a first step of heating a to-be-processed substrate arranged in a vacuum vessel and depositing a metal film on the substrate by physical vapor deposition using a target; and a second step of supplying a gas containing an element for oxidizing a metal film in the vacuum vessel to oxidize the metal film by a thermal oxidation reaction.

Further, another aspect of the present invention is a computer readable recording medium having a program recorded therein for causing a computer to execute a method for forming a MOS-FET including a high-k dielectric film, the method comprising: a first step of heating a to-be-processed substrate arranged in a vacuum vessel and depositing a metal film on the to-be-processed substrate by physical vapor deposition using a target; and a second step of supplying a gas containing an element for oxidizing a metal film in the vacuum vessel to oxidize the metal film by a thermal oxidation reaction.

According to the present invention, a method for forming a metal oxide film on a to-be-processed substrate by physical vapor deposition using a sputtering target, while heating the substrate arranged in a vacuum vessel, performs a first step of depositing the metal film on the substrate and a second step of, without including a deposition step of a metal film, supplying a gas containing an element oxidizing the metal film to oxidize the metal film by only a thermal decomposition reaction. This enables a metal oxide film having few oxygen deficiencies to be formed in one and the same vacuum vessel, in which the leak current due to remained C does not increase and formation of traps in the metal oxide film derived from plasma damage is suppressed.

### BRIEF DESCRIPTION OF THE DRAWINGS

FIG. 1 is an outline view illustrating a substrate processing apparatus according to the present invention;

FIG. 2 is a flowchart describing a control mechanism in one embodiment of the present invention;

FIG. 3 is a flowchart describing a control mechanism in another embodiment of the present invention;

FIG. 4 is a flowchart describing a control mechanism in further another embodiment of the present invention;

FIG. 5 is a schematic view illustrating a control mechanism disposed at a substrate processing apparatus used in the present invention;

FIG. 6 illustrates the procedure of a first step and a second step of forming a metal oxide film according to the present invention;

FIG. 7 is a diagram illustrating a structure of a MOS-FET manufactured by the substrate processing method and the substrate processing apparatus according to the present invention;

FIG. 8 is a diagram illustrating a cross-sectional view of a MIS capacitor of a first embodiment of the present invention;

FIG. 9 is a diagram illustrating the relationship between the target power and the oxygen flow rate according to the first embodiment of the present invention;

FIG. 10 is a diagram illustrating the relationship between the target power and the oxygen flow rate according to the first embodiment of the present invention;

FIG. 11 is diagram illustrating the steps of a method for manufacturing a semiconductor device according to a second embodiment of the present invention; and

FIG. 12 is diagram illustrating the steps of a method for manufacturing a semiconductor device according to a third embodiment of the present invention.

### DESCRIPTION OF EMBODIMENTS

Hereinafter, with reference to drawings, embodiments of the present invention will be described, however, the present invention should not be limited to the embodiments.

The present invention is based on a new finding that, by carrying out in one and the same vacuum vessel, while heating the substrate, a first step of depositing a metal film on a to-be-processed substrate and a second step of, without including a deposition step of a metal film, supplying a gas containing an element oxidizing the metal film in the vessel to oxidize the metal film by a thermal decomposition reaction, oxygen deficiencies in the metal oxide can be compensated without accompanying formation of trap sites due to plasma damage in the metal oxide film.

The reason why the inventor of the present invention has reached the new finding is as follows. That is, when the deposition step and the oxidation step of a metal film are carried out in different vessels, respectively, since there is a concern that only the surface area of the metal film may be oxidized, completely oxidizing a metal film with a thickness of, e.g., 20 nm into a perfect insulating film using the different vessels seems to be difficult. Moreover, there occurs a problem in that diffusion of metal elements remained in the film due to oxygen deficiencies in the film into the under substrate accelerates an interface reaction to form an interface layer. On the other hand, according to the present invention, since the deposition step and the oxidation step of a metal film are carried out in one and the same vessel, it is not necessary to have a concern that only the surface area of the metal film may be oxidized. Moreover, since the oxygen deficiencies in the film are suppressed, formation of the interface layer by the reaction between the metal elements and the under substrate can be prevented or suppressed.

A first feature of the present invention is based on the new finding, specifically in carrying out in one and the same vacuum vessel, while heating the substrate, a first step of depositing a metal film on a to-be-processed substrate arranged in a vacuum vessel by physical deposition using a target and a second step of supplying a gas containing an element oxidizing the metal film to oxidize the metal film by a thermal oxidation reaction.

Next, the configuration and the operation of a substrate processing apparatus together with a substrate processing method according to the present invention will be described.

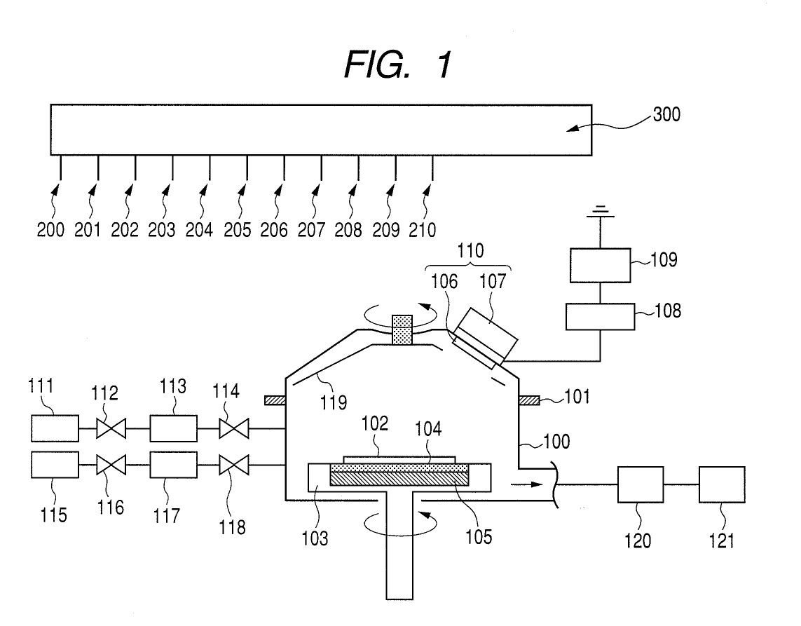

The outline view of a processing apparatus according to the present invention is illustrated in FIG. 1. A film forming treatment chamber (vacuum vessel) 100 is configured to be heated to a predetermined temperature by a heater 101. It is preferable for the inner wall of the film forming treatment chamber to be set to a temperature or higher than the temperature, at which an oxidized gas has a sufficient vapor pressure. A to-be-processed substrate 102 is heated to a predetermined temperature by a heater 105 via a susceptor 104 incorporated in a substrate holding table 103. In view of achieving a uniform film thickness, it is preferable that the substrate holding table 103 can rotate at a predetermined rotation number. In a first step, metal film deposition is carried out by supplying electric power to a target 106 from a high frequency power source 109 via a matching box 108 and a magnet unit 107. In FIG. 1, reference numeral 110 is designated as a cathode. At that time, an inert gas involving only in sputtering is introduced into the film forming treatment chamber 100 from an inert gas source 111 via a valve 112, a mass-flow controller 113, and a valve 114.

Next, in a second step, a gas involving in oxidation of a metal film is introduced into the film forming treatment chamber 100 from an oxidation gas source 115 via a valve 116, a mass-flow controller 117, and a valve 118. The inert gas in the first step and the oxidation gas in the second step are exhausted by an exhaustion pump 121 via a conductance valve 120. Pressures in the film forming treatment chamber in the first and the second steps are controlled to predetermined values, by the conductance valve 120.

The valves 112, 114, 116 and 118 can carry out open/close control by a control device 300 via controlling input/output ports 200, 201, 202 and 203, respectively. Moreover, as for the mass-flow controllers 113 and 117, the flow rates can be controlled by the control device 300 via controlling input/output ports 204 and 205, respectively. Moreover, as for the conductance valve 120, the degree of opening can be adjusted by the control device 300 via a controlling input/output port 206. Moreover, as for the heater 105, the temperature can be adjusted by the control device 300 via a controlling input/output port 207. Moreover, as for the rotational state of the substrate holding table 103, the rotation number can be adjusted by the control device 300 via an input/output port 208. Moreover, as for the high-frequency power source 109, the frequency and the supply power can be adjusted by the control device 300 via an input/output port 209. Moreover, as for the matching box 108, the matching of supplied power can be adjusted by the control device 300 via an input/output port 210.

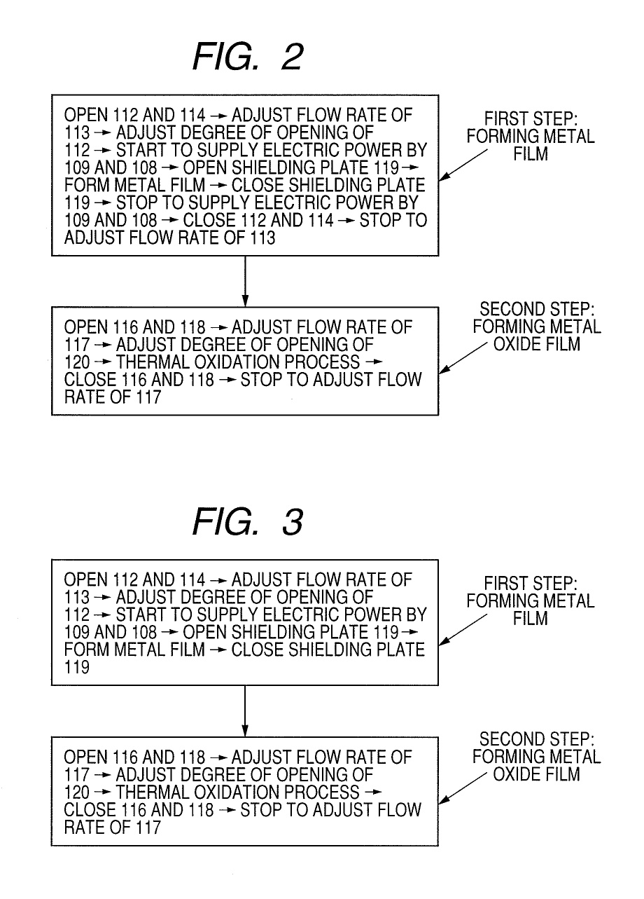

FIG. 2 is a flowchart describing the control mechanism of a substrate processing apparatus involving in a metal oxide film formation step, according to the present invention.

First, a first step of forming a metal film according to the present invention will be described. The control device 300 introduces an inert gas from the inert gas source 111 into the film forming treatment chamber 100 by opening the valves 112 and 114 and adjusting the flow rate while controlling the mass-flow controller 113. It is preferable for the inert gas to contain at least one gas selected from Ar, Kr and Xe. At that time, the control device 300 adjusts the partial pressure of the inert gas in the film forming treatment chamber 100 to a predetermined pressure by the conductance valve 120.

Next, the control device 300 supplies desired electric power to the target 106 by controlling the high frequency power source 109 and the matching box 108. Next, the control device 300 opens a shielding plate 119 shielding the target 106 and the to-be-processed substrate 102, to form a metal film on the substrate 102. At that time, the control device 300 can set the temperature of the to-be-processed substrate 102 to a predetermined temperature by controlling the heater 105. The predetermined temperature can be set suitably depending on an oxidation gas to be introduced, for example, when H₂O is used as the oxidization gas, a desired metal oxide film can be formed at a substrate temperature of 300° C. Moreover, when O₂, O₃, N₂O and D₂O are used as the oxidization gas, a desired metal oxide film can be formed at a substrate temperature of 600° C.

While heating the to-be-processed substrate 102 in this manner, a metal film is formed on the to-be-processed substrate 102 by physical vapor deposition using a target. The control device 300 can control the formation rate and the thickness of the film to be formed by the power and time supplied to the target 106 and the time during which the shielding plate 119 is opened. After a predetermined metal film is formed, the control device 300 stops to supply power by closing the shielding plate 119 and by controlling the high-frequency power source 109 and the matching box 108, to stop forming a metal film on the to-be-processed substrate 102. Furthermore, the control device 300 stops to introduce the inert gas in the film forming treatment chamber 100 by closing the valves 112 and 114 and by controlling the mass-flow controller 113 to stop adjusting the flow rate, causing the first step of forming a metal film to be completed.

In addition, the metal film to be formed on the to-be-processed substrate 102 preferably contains at least one element selected from the group consisting of Hf, Zr, Al, La, Pr, Y, Ti, and, Ta.

Next, a second step of forming a metal oxide film according to the present invention will be described. In the film forming treatment chamber 100 in which the first step is carried out, the control device 300 opens the valves 116 and 118, controls the mass-flow controller 117 to adjust the flow rate, and introduces an oxidation gas (oxidizing agent) from the oxidation gas source 115 into the film forming treatment chamber 100. The oxidation gas preferably contains at least an atom or a molecule selected from the group consisting of an oxygen radical atom, an oxygen radical molecule, O₂, O₃, N₂O, H₂O, and D₂O (heavy water). At that time, the control device 300 can adjust the partial pressure of the inert gas in the film forming treatment chamber 100 to a desired pressure by the conductance valve 120. Formation of the metal oxide film can be controlled by the introduction time of the oxidation gas and the temperature of the to-be-processed substrate 102. That is, the control device 300 sets the temperature of the to-be-processed substrate 102 to a predetermined temperature by controlling the heater 105. It is preferable for the temperature of the to-be-processed substrate 102 to be equal to or higher than 200° C. in order to accelerate the thermal oxidation reaction, and it is preferable for the temperature to be equal to or lower than 600° C. in order to suppress oxidation of the under substrate.

Next, the control device 300 completes the second step of forming a metal oxide film by closing the valves 116 and 118 and by controlling the mass-flow controller 117 to stop adjusting the flow rate. As described above, since the formation of a metal oxide film according to the present invention is carried out by only the thermal oxidation reaction of the metal film due to the oxidation gas, oxygen deficiencies can be compensated without forming traps derived from plasma damage in the metal oxide film.

Moreover, as described in FIG. 3, in order to prevent or suppress oxidation of the surface of a target due to an oxidation gas, the surface of the target may be always cleaned by continuing supplying electric power to the target 106 in the first step and by also supplying electric power to the target 106 in the second step. This results in an effect that the fluctuation of the film formation rate accompanied with the oxidation of the surface of the target can be suppressed.

Moreover, although the first step and the second step are carried out once, respectively, in FIGS. 2 and 3, a metal oxide film with a desired thickness may be formed by repeating a plurality of sets of the first step and the second step. This results in an effect that formation of oxygen deficiencies can be suppressed even for a thick metal oxide with a thickness of 20 nm.

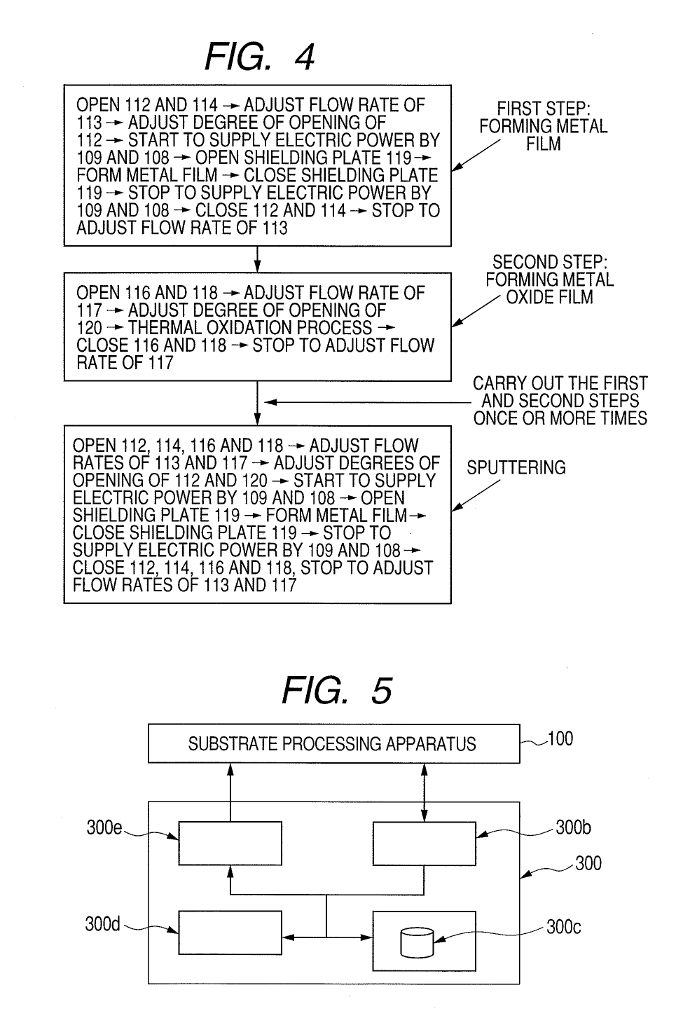

FIG. 4 is a flowchart describing another control mechanism of a substrate processing apparatus involving in the metal oxide film formation step in the present invention.

The feature of the control device according to the present embodiment is in that the device is controlled so as to carry out the first step and the second step described in FIG. 2 alternately once or more times while heating the to-be-processed substrate 102 arranged in the film forming treatment chamber 100, and after that, to carry out sputtering while supplying a mixture gas of the oxidation gas and the inert gas. This results in an effect that formation of trap sites in the metal oxide film derived from plasma damage can be reduced and the oxygen deficiencies in the metal oxide can be compensated.

Specifically, as described in FIG. 4, after carrying out the first step and the second step at least once, respectively, the control device 300 performs sputtering method while supplying the mixture gas of the oxidation gas and the inert gas. That is, the control device 300 opens the valves 112, 114, 116 and 118, adjusts the flow rates by controlling the mass-flow controllers 113 and 117, and introduces the inert gas from the inert gas source 111 and the oxidation gas from the oxidation gas source 115 into the film forming treatment chamber 100, respectively. The control device 300 controls the partial pressures of the inert gas and the oxidation gas in the film forming treatment chamber 100 by controlling the conductance valve 120.

Next, by controlling the high-frequency power source 109 and the matching box 108, the control device 300 applies desired electric power to the target 106, and by opening the shielding plate 119, forms a metal film on the substrate 102 by means of sputtering. Next, the device 300 closes the shielding plate 119, and by controlling the high-frequency power source 109 and the matching box 108, stops to supply electric power to the target 106. Next, the device 300, by closing the valves 112, 114, 116 and 118, and by controlling the mass-flow controllers 113 and 117, stops to adjust the flow-rate. By these steps, the sputtering process mentioned above will be completed.

FIG. 5 is a schematic view illustrating the control device 300 that controls the substrate processing apparatus 100 used for the present invention. The control device 300 includes: an input section 300b; a storage section 300c having a program and data; a processor 300d; and an output section 300e, and it is basically configured with a computer and controls the corresponding substrate processing apparatus 100.

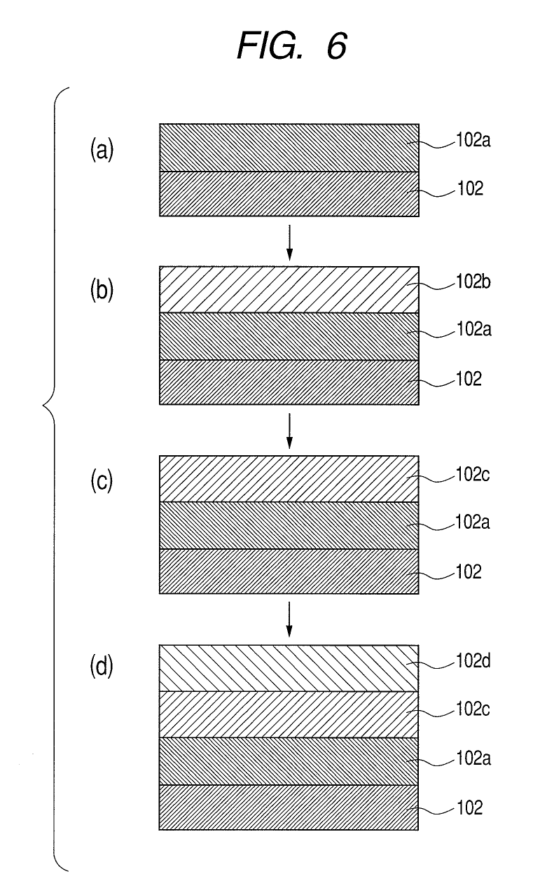

FIG. 6 illustrates the procedures of a first step and a second step of forming a metal oxide film according to the present invention

Step-1: By vapor deposition, depositing a preliminary film for a high-k dielectric.

Step-2: Performing thermal annealing process under an oxygen atmosphere to form the high-k dielectric.

Step-3: Cooling a wafer.

Step-4: By vapor deposition, depositing a metal electrode material.

### Detailed Description of Vapor-Deposition Method

### Step-1

A starting wafer may be structured so as to have or not to have a thin SiO₂ or SiON layer 102a deposited initially on a to-be-processed substrate 102. In FIG. 6(a), the SiO₂ or SiON layer 102a is formed on the to-be-processed substrate 102. A starting material 102b for a high-k dielectric is deposited on the substrate 102 by vapor deposition, using the substrate processing apparatus 100 illustrated in FIG. 1 (FIG. 6(b)). The starting material 102b may be a metal, and preferably it is a heat-resistant metal, such as Al, Hf, Ta and Zr; a metal nitride, such as ALN, HfN, TaN and TiN; a metal alloy, such as AlTi, HfTa and HfTi; a metal-semiconductor alloy, such as HfSi; and a metal alloy nitride, such as TaSiN. Moreover, in view of increasing permittivity, the materials mentioned above may be added with La, Pr, Y and Ti.

Similarly, in this case, the starting material 102b can have a lamination structure of the two or more films mentioned above. Such a lamination structure of two or more films includes, for example, Hf/SiN/Hf and HfN/AlN/Hf.

Usually, Hf, Zr, Ti or Ta is used as the metal target 106. However, another metal target can also be used. When a metal-semiconductor alloy is deposited, the semiconductor material is preferably Si.

Although not so important, the film thickness of the starting material 102b mentioned above is usually maintained to be equal to or smaller than 5 nm, in general, it is maintained to be about 2 nm.

### Step-2

As mentioned above, after the starting film 102b is deposited by vapor deposition, the to be processed substrate 102 is generally heated to a high temperature over 400° C. under an oxygen gas atmosphere, and this oxidizes the starting film 102b, which is a starting material, (FIG. 6(c)) to form a high-k dielectric 102c. The heating process can be carried out in one step or in two or more steps. Usually, in order to control a chemical reaction during an annealing process, it is appropriate to carry out the heating process in two or more steps. For example, at first, the film is heated to 400° C., and the metal element in the starting film 102b, which is a starting material, is oxidized. If the film is directly heated to a high temperature of, e.g., 800° C., in some cases, the metal elements in the starting film form a stable silicon compound of the element that exhibits metallic properties. If the film is appropriately oxidized at a relatively low temperature of, e.g., 400° C., the film can be heated to a high temperature of, e.g., 900° C. preferably under an inert gas atmosphere. When a metal laminated body including different metals is used as the starting material 102b, a high temperature annealing has an important role in diffusion between respective materials and for forming a uniform film composition.

### Step-3

After the heat annealing process is completed, the to-be-processed substrate 102 is transferred to a cooling module (not illustrated in the figure), where it is cooled to a desired temperature, preferably to a room temperature.

### Step-4

The substrate 102 is transferred to a PVD module (not illustrated in the figure), where a gate electrode 26 is deposited by vapor deposition thereon (FIG. 6(d)).

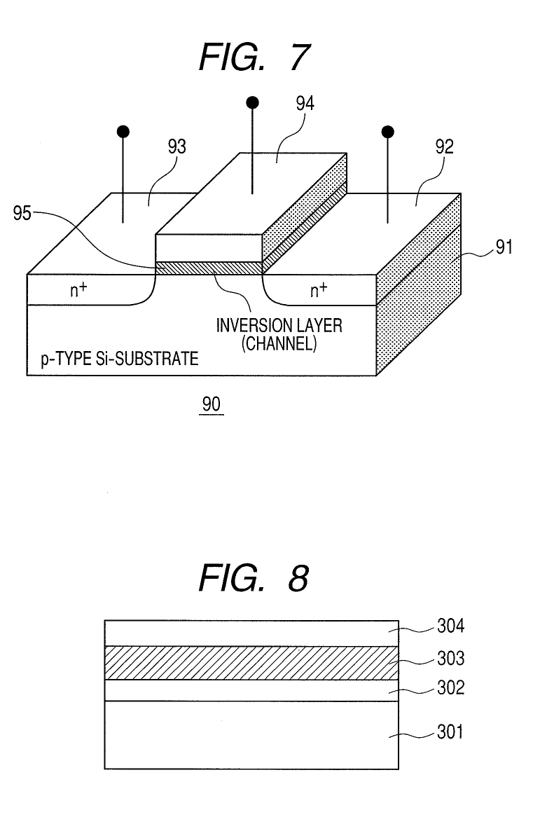

A MOS field effect transistor (FET) 90 of FIG. 7 is manufactured by the above-mentioned procedures according to the present invention. An HfO film is used as a dielectric gate insulating film (high-k dielectric film) 95 under a gate electrode 94 between a source region 92 and a drain region 93 of a Si substrate 91. Otherwise, Al₂O₃, HfN, HfON, HfLaO, HfLaN, HfLaON, HfAlLaO, HfAlLaN, HfAlLaON, LaAlO, LaAlN, LaAlON, LaO, LaN and LaON may be used for the dielectric gate insulating film (high-k dielectric film) 95. The relative permittivity, the fixed charge density, the thickness of the gate insulating layer, and the interface state density are within a range from 3.9 to 100, 0 to 1×10¹¹ cm⁻², 0.5 to 5.0 nm, and 1×10¹¹ cm⁻² or less, respectively.

### First Embodiment

With reference to drawings, the first embodiment of the present invention will be described in detail. FIG. 8 illustrates a dielectric film according to the first embodiment. An HfO₂ film 303 was deposited on a silicon substrate 301 having a silicon oxide film 302 with a thickness of 3 to 5 nm thereon, using the substrate processing apparatus 100 illustrated in FIG. 1. An Hf metal target was used as a target, argon was used as a sputtering gas, and oxygen was used as an oxidation gas. The substrate temperature, the target power, the pressure of the sputtering gas, the flow rate of argon, and the flow rate of the oxygen gas may be determined suitably within the ranges of 27 to 600° C., 50 to 1000 W, 0.02 to 0.1 Pa, 1 to 100 sccm, and 1 to 100 sccm, respectively.

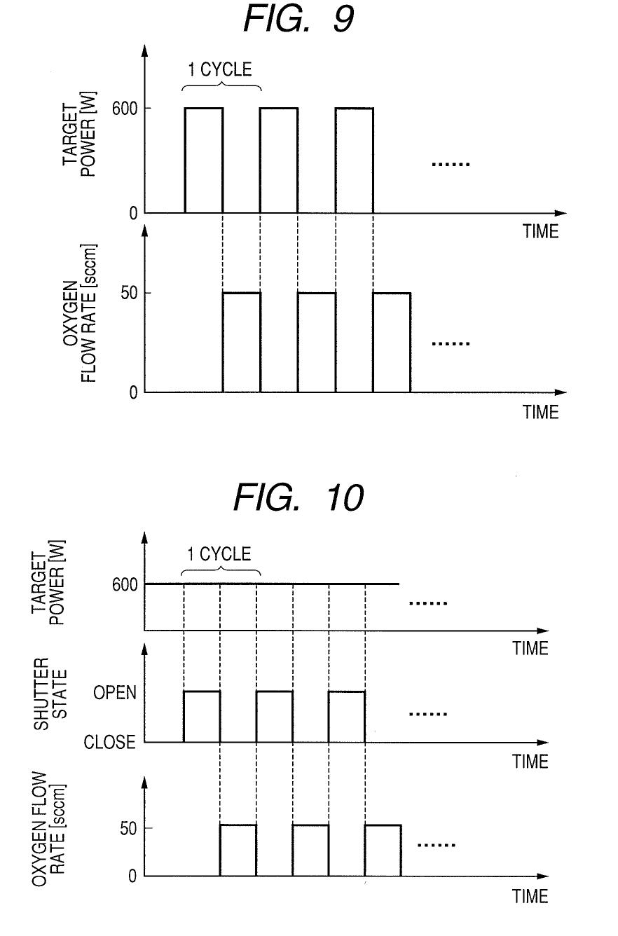

Here, a film was formed under the following conditions, the substrate temperature: 300° C.; the Hf target power: 600 W; the pressure of the sputtering gas: 0.03 Pa; the flow rate of Ar: 25 sccm; and the flow rate of oxygen gas: 50 sccm. FIG. 9 illustrates the outlines of a step of inputting the target power and a step of supplying an oxygen gas according to the present embodiment. As illustrated in FIG. 9, defining a step of forming an Hf metal film and a step of oxidation by an oxygen gas as one set of cycle, HfO₂ with a desired thickness can be formed by repeating the set for a plurality of times. Moreover, although the deposition step of a metal film was controlled by controlling the power to be input to the target 106, the deposition step may be controlled by OPEN/CLOSE state of a shutter 119 as illustrated in FIG. 10. Where, OPEN state of the shutter is referred to as a state where the opening of the shutter faces the entire surfaces of the target 106, and CLOSE state is referred to as a state where the substrate 102 and the target 106 are shielded by the shutter 119. By always inputting power to the target 106, oxidation of the target 106 due to an oxygen gas is suppressed, thereby enabling the decrease of the deposition rate accompanied with the oxidation of the target 106 to be prevented.

By using the above-mentioned formation step, HfO₂ with a thickness of 20 nm was formed. Next, a TiN film 304 with a thickness of 10 nm was deposited on HfO₂ by means of a sputtering method. A Ti metal target was used as a target, and argon and nitrogen was used as a sputtering gas. Next, a MIS capacitor was formed by working the TiN film to a desired size using a lithography technology and an RIE technology.

As a result of evaluating the CV (Capacitance-Voltage) characteristic of HfO₂ produced as mentioned above, the hysteresis shift resulting from the oxygen deficiencies in the film was not observed. Moreover, when the cross-section of the interface between the silicon dioxide film of the under layer and HfO₂ was observed by a TEM, the interface reaction layer due to diffusion of Hf was not observed at the interface. Thus, according the first embodiment of the present invention, the method for forming a metal oxide film on a to-be-processed substrate by physical vapor deposition using a sputtering target, while heating the to-be-processed substrate arranged in a vacuum vessel, performs a first step of depositing a metal film and a second step of, without including a deposition step of the metal film, supplying a gas containing an element that oxidizes the metal film to oxidize the metal film by only a thermal decomposition reaction. It was confirmed that, by these steps, a film was obtained in one and the same vacuum vessel, in which the leak current due to remained C did not increase, the formation of traps in the metal oxide film derived from plasma damage was suppressed, and few oxygen deficiencies were present.

Moreover, in the present embodiment, it was confirmed that the same effects was also obtained even when Al₂O₃, ZrO₂, Ta₂O₃, TiO₂, La₂O₃ and Y₂O₃ were formed using Al, Zr, Ta, Ti, La and Y as a metal film.

Moreover, although oxygen was used as the oxidation gas in the present embodiment, even when one oxidation gas selected from the group consisting of an oxygen radical atom, O₃, N₂O, H₂O and D₂O was used, the same effects was obtained.

### Second Embodiment

### Embodiment Applied for a Gate Insulating Film

With reference to drawings, the second embodiment of the present invention will be described in detail.

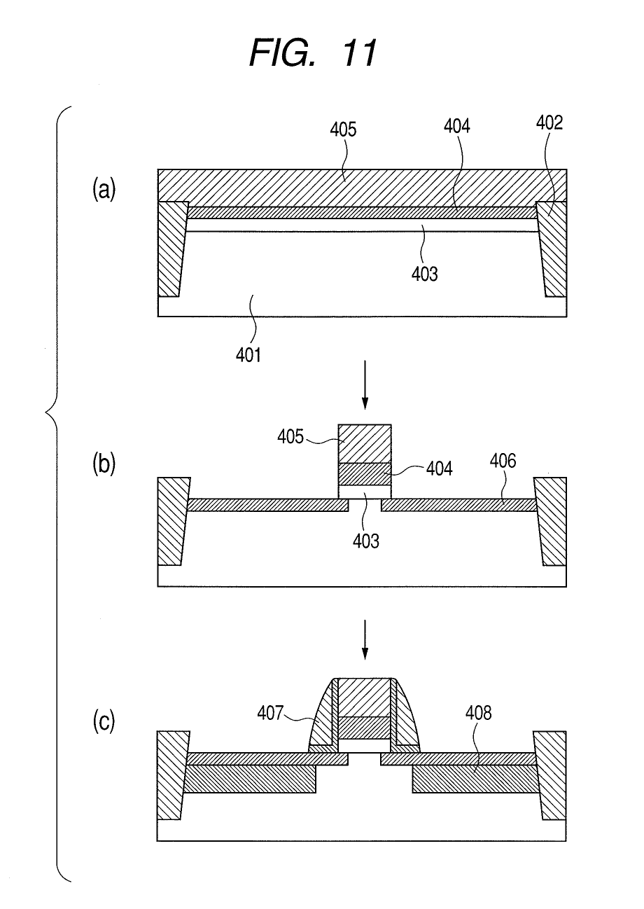

FIGS. 11(a) to 11(c) illustrate each step of a method for manufacturing a semiconductor device according to the second embodiment of the present invention, respectively.

First, as illustrated in FIG. 11(a), a device isolation region 402 was formed on the surface of a silicon substrate 401 by an STI (Shallow Trench Isolation) technology. Subsequently, a silicon oxide film 403 with a thickness of 1.8 nm was formed on the surface of the device-isolated silicon substrate 401 by means of a thermal oxidation method. After that, by the same method as that of the first embodiment, HfO₂ film was formed so as to have a thickness within a range of 1 to 10 nm.

Next, poly-Si 405 with a thickness of 150 nm was formed on a dielectric film 404, and then the laminated body illustrated in FIG. 11(a) was worked so as to form a gate electrode as illustrated in FIG. 11(b) using a lithography technology and an RIE technology. Subsequently, by ion implantation, an extension region 406 was formed in a self-aligned manner using the gate electrode as a mask.

Further, as illustrated in FIG. 11(c), by sequentially depositing a silicon nitride film and a silicon oxide film thereon and then by carrying out etching back, a gate side wall 407 was formed. In this state, by carrying out ion implantation again and then by carrying out activation annealing, a source/drain region 408 was formed.

As a result of evaluating the electrical properties of the produced semiconductor device, a hysteresis shift resulting from oxygen deficiencies in the film was not observed. Moreover, when the cross-section was observed by a TEM, the interface reaction layer formed by diffusion of Hf in the interface between the silicon oxide under film and HfO₂ was not observed.

Moreover, in the present embodiment, it was confirmed that the same effects was also obtained even when Al₂O₃, ZrO₂, Ta₂O₃, TiO₂, La₂O₃ and Y₂O₃ were formed using Al, Zr, Ta, Ti, La and Y as a metal film.

Moreover, although oxygen was used as the oxidation gas in the present embodiment, even when one oxidation gas selected from the group consisting of an oxygen radical atom, O₃, N₂O, H₂O and D₂O was used, the same effects were obtained.

### Third Embodiment

### Embodiment Applied to the Blocking Film of a Nonvolatile Memory Element

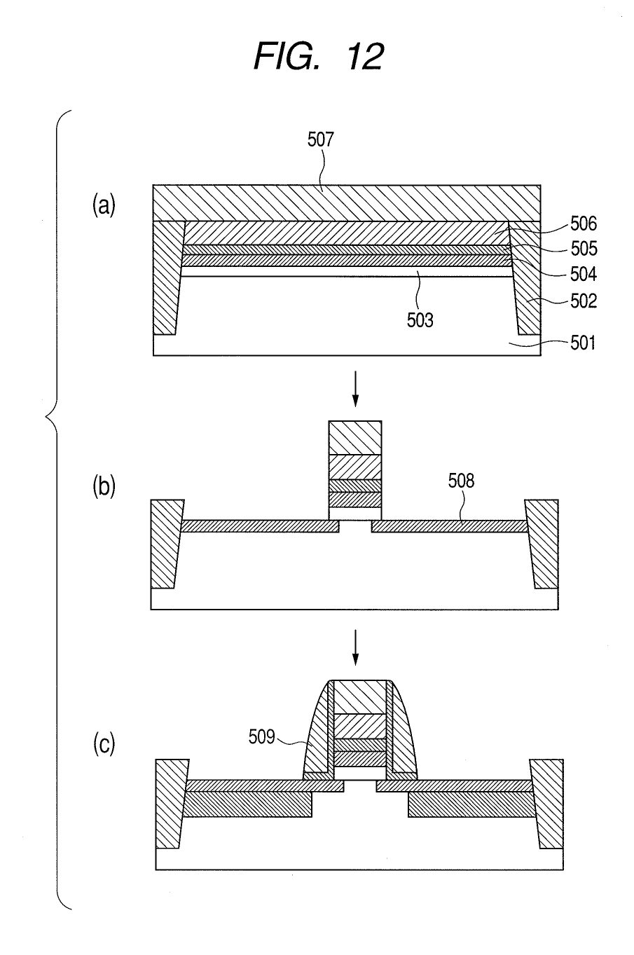

FIGS. 12(a) to 12(c) are cross-section views illustrating each step of a method for manufacturing a semiconductor device according to the third embodiment of the present invention, respectively.

First, as illustrated in FIG. 12(a), a device isolation region 502 was formed on the surface of a silicon substrate 501 by an STI technology. Subsequently, as a first insulating film 503, a silicon oxide film with a thickness of 3 to 10 nm was formed on the surface of the device-isolated silicon substrate 501 by a thermal oxidation method. Subsequently, as a second insulating film 504, a silicon nitride film with a thickness of 3 to 10 nm was formed thereon by means of a LPCVD (Low Pressure Chemical Vapor Deposition) method. Subsequently, as a third insulating film 505, an aluminum oxide film with a thickness of 10 to 20 nm was formed thereon using the substrate processing method and the substrate processing apparatus according to the present invention.

Next, a poly-Si film with a thickness of 150 nm was formed thereon as a gate electrode 506, and then, the laminated body illustrated in FIG. 12(a) was worked so as to form the gate electrode as illustrated in FIG. 12(b) using a lithography technology and an RIE technology. Subsequently, by carrying out ion implantation, an extension region 507 was formed in a self-aligned manner using the gate electrode as a mask.

Further, as illustrated in FIG. 12(c), by sequentially depositing a silicon nitride film and a silicon oxide film thereon and then by carrying out etching back, a gate side wall 508 was formed. In this state, by carrying out ion implantation again and then by carrying out activation annealing, a source/drain region 509 was formed.

As a result of evaluating the electrical properties of the produced semiconductor device, degradation of the retention characteristic resulting from oxygen deficiencies in the aluminum oxide film was not observed.

As mentioned above, according to the present embodiment, using the substrate processing method and the substrate processing apparatus according to the present invention for forming the blocking insulating film of an MONOS nonvolatile memory element, a semiconductor device capable of improving the retention characteristic was able to be obtained.

Moreover, in the present embodiment, it was confirmed that the same effects were obtained even when Al₂O₃, ZrO₂, Ta₂O₃, TiO₂, La₂O₃ and Y₂O₃ were formed using Al, Zr, Ta, Ti, La, and Y as a metal film.

Moreover, although oxygen was used as the oxidation gas in the present embodiment, even when one oxidation gas selected from the group consisting of an oxygen radical atom, O₃, N₂O, H₂O and D₂O was used, the same effects were obtained.

### Other Embodiments

In addition, the control mechanism 300 may be provided separately from the substrate processing apparatus 301, and may be built in the substrate processing apparatus 301.

A processing method in which a program for operating the configurations of the embodiments mentioned above is stored in a storage medium so as to achieve the functions of the embodiments, and the program stored on the storage medium is read out as a code and is executed by a computer, is also included in the scope of the embodiments. That is, a computer-readable storage medium is also included in the scope of the embodiments. Moreover, not only the storage medium on which the computer program is stored, but also the computer program itself is included in the scope of the embodiments.

A floppy (registered trademark) disk, a hard disk, an optical disk, a magneto-optical disk, a CD-ROM, a magnetic tape, a non-volatile memory card and a ROM can be used as such a storage medium.

Moreover, not only a single program stored on the storage medium for executing processing, but also a program running on an OS for executing the operations of the embodiments together with the functions of other software and another extension board, is included in the scope of the embodiments.

1. A substrate processing method comprising:
a first step of heating a to-be-processed substrate arranged in a vacuum vessel and depositing a metal film on the to-be-processed substrate by physical vapor deposition using a target; and
a second step of supplying a gas containing an element for oxidizing the metal film in the vacuum vessel to oxidize the metal film by a thermal oxidation reaction, wherein
after the first step and the second step are carried out alternately at least once, sputtering is performed while a mixture gas of an element containing an element for oxidizing the metal film and an inert gas is supplied.

2. A substrate processing method according to claim 1, wherein the first step and the second step are carried out alternately for a plurality of times.

3. (canceled)

4. A substrate processing method according to claim 1, wherein
the gas containing the element for oxidizing the metal film is a gas containing an atom or a molecule selected from a group consisting of an oxygen radical atom, an oxygen radical molecule, O₂, O₃, N₂O, H₂O and D₂O.

5. A substrate processing method according to claim 1, wherein
the metal film contains at least one element selected from a group consisting of Hf, Zr, Al, La, Pr, Y, Ti and Ta.

6. A substrate processing apparatus, comprising:
a film forming treatment chamber;
a substrate holding table for holding a to-be-processed substrate in the film forming treatment chamber;
a heating device for adjusting the temperature of the substrate holding table;
an oxidation gas introduction means for introducing an oxidation gas in the film forming treatment chamber;
an inert gas introduction means for introducing an inert gas in the film forming treatment chamber;
a high-frequency supply means for supplying a high-frequency electric power to a target containing an element constituting a metal film; and
a control mechanism, wherein
when a metal film is formed on the to-be-processed substrate in the film forming treatment chamber, the control mechanism controls the heating device so as to heat the to-be-processed substrate and controls the inert gas introduction means and the high-frequency supply means so as to deposit a metal film on the to-be-processed substrate being heated,
when the deposited metal film is oxidized in the film forming treatment chamber, the control mechanism controls the oxidation gas introduction means so as to supply the oxidation gas on the deposited metal film and controls the heating device so as to oxidize the metal film by a thermal oxidation reaction,
the control mechanism is configured so as to carrying out forming a metal film on the to-be-processed substrate and oxidizing the deposited metal film alternately at least once in the film forming treatment chamber; and
the control mechanism, after carrying out the forming and the oxidizing at least once, controls the oxidation gas introduction means, the inert gas introduction means and the high-frequency supply means so as to perform sputtering while supplying a mixture gas of the oxidation gas and the inert gas.

7. (canceled)

8. A method for manufacturing a MOS-FET including a high-k dielectric film, the method comprising:
a first step of heating a to-be-processed substrate arranged in a vacuum vessel and depositing a metal film on the to-be-processed substrate by physical vapor deposition using a target; and
a second step of supplying a gas containing an element for oxidizing the metal film in the vacuum vessel to oxidize the metal film by a thermal oxidation reaction, and wherein
after the first step and the second step are carried out alternately at least once, sputtering is performed while a mixture gas of an element containing an element for oxidizing the metal film and an inert gas is supplied.

9. A method for manufacturing a non-volatile memory element including a High-k dielectric film, the method comprising:
a first step of heating a to-be-processed substrate arranged in a vacuum vessel and depositing a metal film on the to-be-processed substrate by physical vapor deposition using a target; and
a second step of supplying a gas containing an element for oxidizing the metal film in the vacuum vessel to oxidize the metal film by a thermal oxidation reaction, and wherein
after the first step and the second step are carried out alternately at least once, sputtering is performed while a mixture gas of an element containing an element for oxidizing the metal film and an inert gas is supplied.

10. A computer-readable recording medium having a program recorded therein for causing a computer to execute a method for forming a MOS-FET including a high-k dielectric film, the method comprising:
a first step of heating a to-be-processed substrate arranged in a vacuum vessel and depositing a metal film on the to-be-processed substrate by physical vapor deposition using a target; and
a second step of supplying a gas containing an element for oxidizing the metal film in the vacuum vessel to oxidize the metal film by a thermal oxidation reaction, and wherein
after the first step and the second step are carried out alternately at least once, sputtering is performed while a mixture gas of an element containing an element for oxidizing the metal film and an inert gas is supplied.
